(19) United States
(12) Patent Application Publication
(10) Pub. No.: US 2025/0385514 A1
(43) Pub. Date: Dec. 18, 2025

(54) TRANSIENT VOLTAGE PROTECTION DEVICE

(71) Applicant: TDK CORPORATION, Tokyo (JP)

(72) Inventors: Masato HAYATSU, Tokyo (JP); Shunsuke Takahashi, Tokyo (JP); Sota Hiraba, Tokyo (JP); Jun Sato, Tokyo (JP); Yashihiro Shinkai, Tokyo (JP); Naoyoshi Yoshida, Tokyo (JP)

(73) Assignee: TDK CORPORATION, Tokyo (JP)

(21) Appl. No.: 19/219,591

(22) Filed: May 27, 2025

(30) Foreign Application Priority Data
Jun. 18, 2024 (JP) 2024-098172

(51) Int. Cl. H02H 9/04; H05K 1/02

(52) U.S. Cl. CPC H02H 9/044; H05K 1/0259; H05K 2201/0738

(57) ABSTRACT

A transient voltage protection device includes an element body; a first external electrode disposed on a surface of the element body; a second external electrode disposed on the surface of the element body; a first internal electrode; and a second internal electrode. The first internal electrode is disposed in the element body and connected to the first external electrode. The second internal electrode is opposed to the first internal electrode in the element body and is connected to the second external electrode. The first internal electrode includes a first end connected to the first external electrode, and a second end positioned in the element body and separated from the surface of the element body. The second end includes a corner portion including an edge opposed to the second internal electrode. The edge has a curved shape in a plan view of the first internal electrode.

### CROSS-REFERENCE TO RELATED APPLICATIONS

This application is based upon and claims the benefit of priority from Japanese Patent Application No. 2024-098172, filed on Jun. 18, 2024, the entire contents of which are incorporated herein by reference.

### BACKGROUND

### Field

The present disclosure relates to a transient voltage protection device.

### Description of the Related Art

A known transient voltage protections device include an element body, a pair of external electrodes, and a pair of internal electrodes (see, e.g., WO 2014/98084). The pair of external electrodes are disposed on a surface of the element body and are separated from each other. The pair of internal electrodes are opposed to each other in the element body. Each of the pair of internal electrodes is connected to the corresponding external electrode of the pair of external electrodes. Each of the pair of internal electrodes has a rectangular shape in a plan view of the internal electrode. Each of the pair of internal electrodes includes a first end exposed to the surface of the element body and connected to the corresponding external electrode, and a second end positioned in the element body and separated from the surface of the element body.

### SUMMARY

In the above-described transient voltage protection device, discharge occurs between the pair of internal electrodes opposed to each other. In the configuration in which each of the pair of internal electrodes has the rectangular shape in the plan view of the internal electrode, an electric field tends to concentrate at a region of the second end, and discharge tends to locally concentrate. For example, the electric field tends to concentrate at a corner of the second end. In a configuration in which the discharge locally concentrates, a transient voltage protection characteristic may be deteriorated.

An object of one aspect of the present disclosure is to provide a transient voltage protection device capable of controlling deterioration of a transient voltage protection characteristic.

A transient voltage protection device according to one aspect includes an element body, a first external electrode, a second external electrode, a first internal electrode, and a second internal electrode. The external electrode is disposed on a surface of the element body. The second external electrode is disposed on the surface of the element body and is separated from the first external electrode. The first internal electrode is disposed in the element body and connected to the first external electrode. The second internal electrode is opposed to the first internal electrode in the element body and is connected to the second external electrode. The first internal electrode includes a first end exposed to the surface of the element body and connected to the first external electrode, and a second end positioned in the element body and separated from the surface of the element body. The second end includes a first corner portion and a second corner portion that are adjacent to each other in a direction in which the first internal electrode and the second internal electrode are opposed to each other. The first corner portion includes an edge opposed to the second internal electrode. The second corner portion is separated from the second internal electrode than the first corner portion. The edge included in the first corner portion has a curved shape in a plan view of the first internal electrode.

In the above one aspect, the edge included in the first corner portion has the curved shape in the plan view of the first internal electrode. Therefor an electric field tends not to concentrate at a region of the second end, and discharge tends not to concentrate locally. As a result, the above-described one aspect can control deterioration of a transient voltage protection characteristic.

The present disclosure will become more fully understood from the detailed description given hereinafter and the accompanying drawings which are given by way of illustration only, and thus are not to be considered as limiting the present disclosure.

Further scope of applicability of the present disclosure will become apparent from the detailed description given hereinafter. However, it should be understood that the detailed description and specific examples, while indicating examples of the disclosure, are given by way of illustration only, since various changes and modifications within the spirit and scope of the disclosure will become apparent to those skilled in the art from this detailed description.

### BRIEF DESCRIPTION OF THE DRAWINGS

FIG. 1 is a perspective view illustrating a transient voltage protection device according to an embodiment;

FIG. 2 is an exploded perspective view illustrating a configuration of an element body;

FIG. 3 is a plan view illustrating a configuration of an internal electrode and a discharge auxiliary portion;

FIG. 4 is a view illustrating a cross-sectional configuration of the transient voltage protection device according to the present embodiment;

FIG. 5 is a plan view illustrating a configuration of the internal electrode;

FIG. 6 is a plan view illustrating a configuration of another internal electrode; and

FIG. 7 is a plan view illustrating a configuration of a further internal electrode.

### DETAILED DESCRIPTION

Hereinafter, examples of the present disclosure will be described in detail with reference to the accompanying drawings. In the following description, the same elements or elements having the same functions are denoted with the same reference numerals and overlapped explanation is omitted.

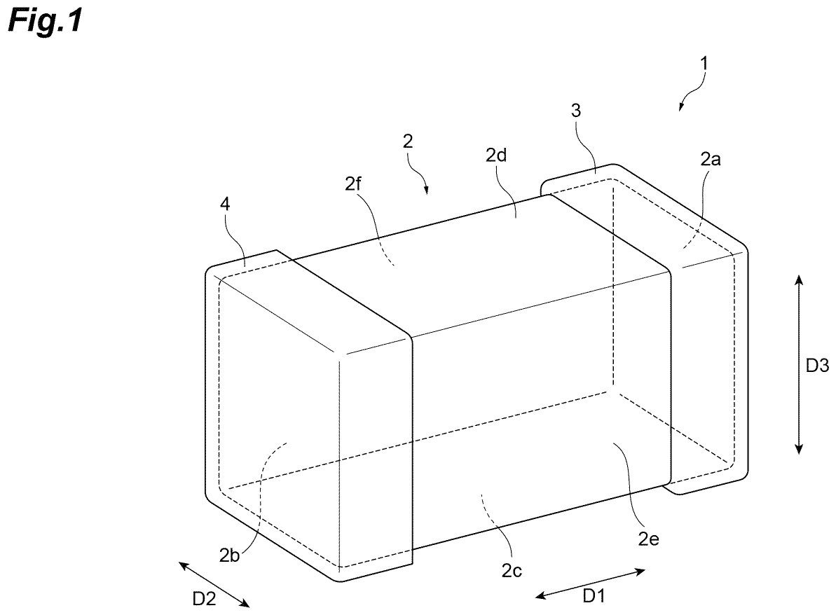

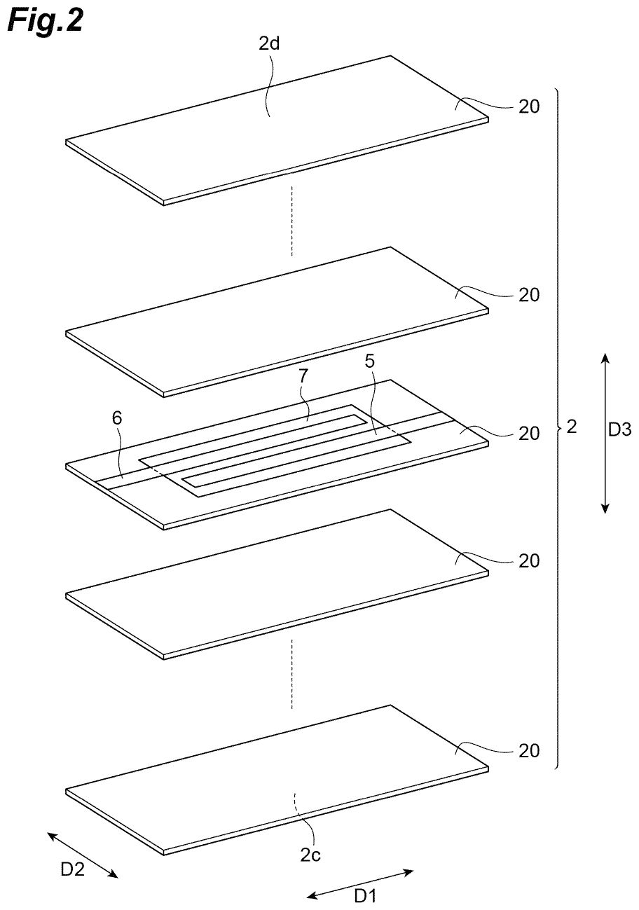

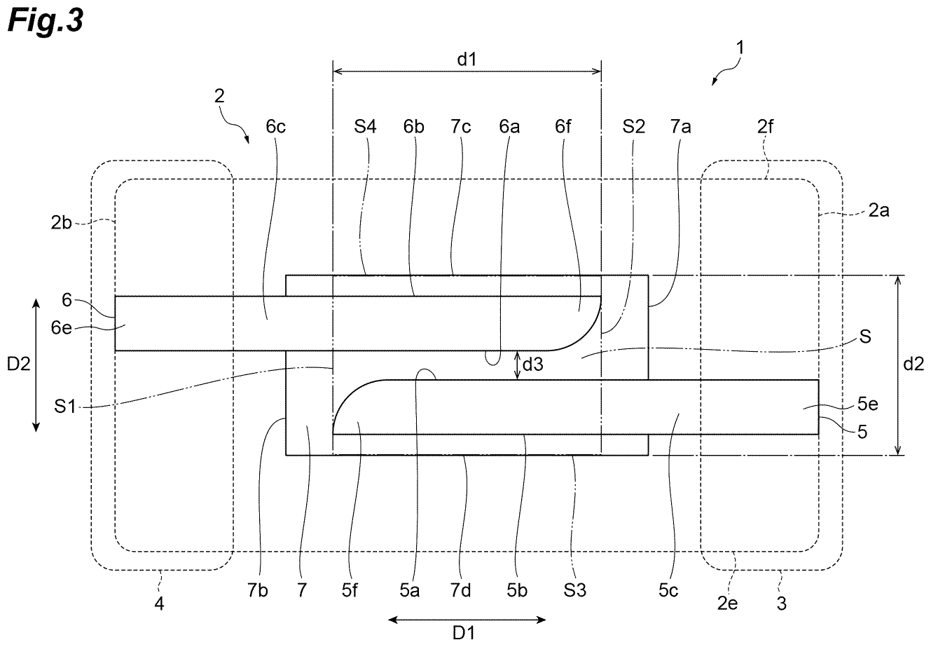

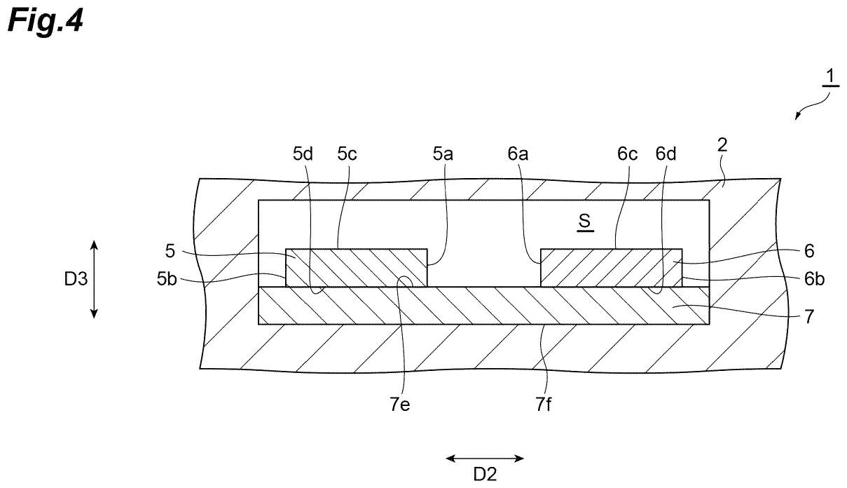

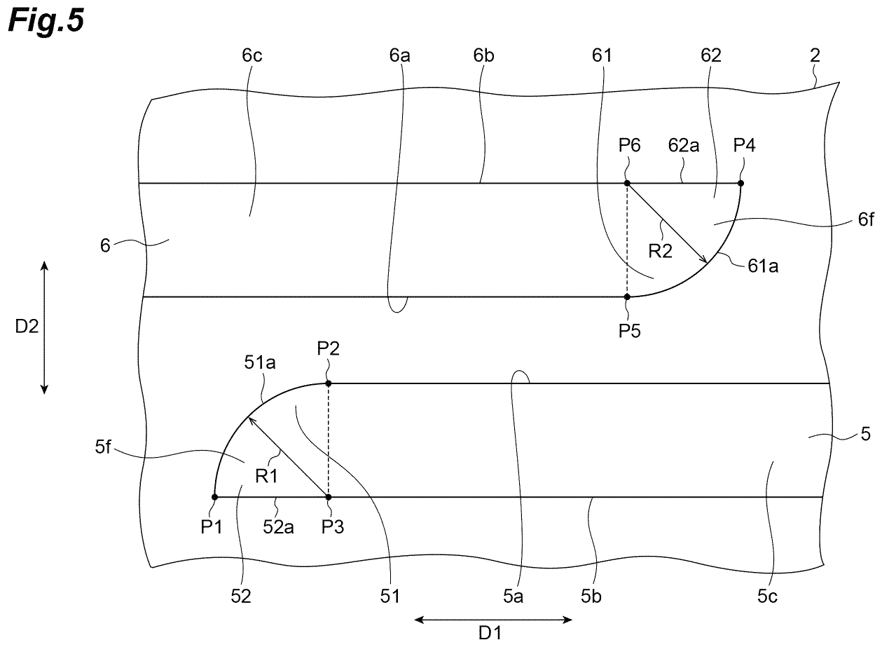

A configuration of a transient voltage protection device 1 according to the present embodiment will be described with reference to FIGS. 1 to 5. FIG. 1 is a perspective view illustrating a transient voltage protection device according to the present embodiment. FIG. 2 is an exploded perspective view illustrating a configuration of an element body. FIG. 3 is a plan view illustrating a configuration of an internal electrode and a discharge auxiliary portion. FIG. 4 is a view illustrating a cross-sectional configuration of the transient voltage protection device according to the present embodiment. FIG. 5 is a plan view illustrating a configuration of the internal electrode.

As illustrated in FIGS. 1 and 2, the transient voltage protection device 1 includes an element body 2, a pair of external electrodes 3 and 4, a pair of internal electrodes 5 and 6, and a discharge auxiliary portion 7. The transient voltage protection device 1 is mounted on an electronic apparatus (not illustrated). The transient voltage protection device 1 protects the electronic apparatus from a transient voltage. The electronic apparatus protected by the transient voltage protection device 1 includes, for example, a circuit board or an electronic component. The transient voltage is caused by, for example, electro-static discharge (ESD).

The element body 2 has a rectangular parallelepiped shape. Examples of the rectangular parallelepiped shape include a rectangular parallelepiped shape in which corner portions and ridge portions are chamfered, and a rectangular parallelepiped shape in which corner portions and ridge portions are rounded. The element body 2 includes a pair of end surfaces 2a and 2b opposed to each other, a pair of side surfaces 2c and 2d opposed to each other, and a pair of side surfaces 2e and 2f opposed to each other. In the present embodiment, the pair of end surfaces 2a and 2b are opposed to each other in a first direction D1, the pair of side surfaces 2e and 2f are opposed to each other in a second direction D2, and the pair of side surfaces 2c and 2d are opposed to each other in a third direction D3. For example, the first direction D1, the second direction D2, and the third direction D3 cross each other. In the present embodiment, the first direction D1, the second direction D2, and the third direction D3 are orthogonal to each other.

A surface of the element body 2 includes the pair of end surfaces 2a and 2b and the four side surfaces 2c, 2d, 2e, and 2f. The four side surfaces 2c, 2d, 2e, and 2f are adjacent to the end surface 2a and the end surface 2b, and extend in the first direction D1 to connect the end surface 2a and the end surface 2b. One of the four side surfaces 2c, 2d, 2e, and 2f includes a mounting surface opposed to the electronic apparatus on which the transient voltage protection device 1 is mounted.

As illustrated in FIG. 2, the element body 2 is configured through laminating a plurality of insulator layers 20 in the third direction D3. The element body 2 includes the plurality of laminated insulator layers 20. In the element body 2, the respective insulator layers 20 are integrated to such an extent that boundaries between the insulator layers 20 cannot be visually recognized. Each of the insulator layers 20 includes, for example, a sintered body of a ceramic green sheet including an insulator material.

The insulator material includes, for example, a ceramic material. The ceramic material is selected from a group consisting of, for example, Fe₂O₃, NiO, CuO, ZnO, MgO, SiO₂, TiO₂, MnCO₃, SrCO₃, CaCO₃, BaCO₃, Al₂O₃, ZrO₂, and B₂O₃. The insulator layer 20 may include a single ceramic material or two or more kinds of ceramic materials. The insulator layer 20 may include glass. The insulator layer 20 may include copper oxide (CuO or Cu₂O) to enable low temperature sintering.

The external electrodes 3 and 4 are disposed on the element body 2. The pair of external electrodes 3 and 4 are disposed on the surface of the element body 2. The external electrodes 3 and 4 are disposed on the element body 2 to be opposed to each other in the first direction D1. The external electrodes 3 and 4 are disposed at opposite end portions of the element body 2 in the first direction D1. The external electrode 4 is separated from the external electrode 3. That is, the external electrodes 3 and 4 are separated from each other. In the present embodiment, the external electrodes 3 and 4 are separated from each other in the first direction D1. That is, in the present embodiment, a direction in which the external electrode 3 and the external electrode 4 are separated from each other includes the first direction D1. For example, in a case where the external electrode 3 includes a first external electrode, the external electrodes 4 includes a second external electrode.

The external electrode 3 is disposed on the end surface 2a. The external electrode 3 is connected to the internal electrode 5. The external electrode 3 is physically and electrically connected to the internal electrode 5. The external electrode 3 covers the end surface 2a. The external electrode 3 also covers a part of each of the side surfaces 2_{c}, 2_{d}, 2ₑ, and 2_{f}. The part of each of the four side surfaces 2_{c}, 2_{d}, 2ₑ, and 2_{f} covered with the external electrode 3 is positioned closer to the end surface 2a on the corresponding side surface. The external electrode 3 is disposed on the entire surface of the end surface 2a and at end portions of the side surfaces 2c, 2d, 2e, and 2f closer to the end surface 2a.

The external electrode 4 is disposed on the end surface 2b. The external electrode 4 is connected to the internal electrode 6. The external electrode 4 is physically and electrically connected to the internal electrode 6. The external electrode 4 covers the end surface 2b. The external electrode 4 also covers a part of each of the four side surfaces 2c, 2d, 2e, and 2f. The part of each of the four side surfaces 2c, 2d, 2e, and 2f covered with the external electrode 4 is positioned closer to the end surface 2b on the corresponding side surface. The external electrode 4 is disposed on the entire surface of the end surface 2b and on the end portions of the side surfaces 2c, 2d, 2e, and 2f closer to the end surface 2b.

The internal electrodes 5 and 6 are disposed in the element body 2. The internal electrode 6 is opposed to the internal electrode 5 in the element body 2. That is, the internal electrodes 5 and 6 are opposed to each other in the element body 2. In the present embodiment, the internal electrodes 5 and 6 are opposed to each other in the second direction D2. That is, in the present embodiment, a direction in which the internal electrode 5 and the internal electrode 6 are opposed to each other includes the second direction D2. Each of the internal electrodes 5 and 6 extends in the first direction D1. The internal electrode 5 is disposed closer to the side surface 2e. The internal electrode 6 is disposed closer to the side surface 2f.

The internal electrodes 5 and 6 are disposed in the same layer, for example. In the present embodiment, the internal electrodes 5 and 6 are disposed at the same height position, i.e., at the same laminating position in the third direction D3. As illustrated in FIG. 2, the internal electrodes 5 and 6 are disposed on the same insulator layer 20. The internal electrodes 5 and 6 are disposed substantially at the center in the third direction D3, i.e., a laminating direction of the insulator layer 20.

As shown in FIG. 3, the internal electrode 5 includes a pair of end edges 5a and 5b, a pair of faces 5c and 5d, and a pair of ends 5e and 5f. The pair of end edges 5a and 5b are opposed to each other. In the present embodiment, the pair of end edges 5a and 5b are opposed to each other in the second direction D2. The end edge 5a is opposed to the internal electrode 6. The end edge 5a is opposed to the internal electrode 6 in the second direction D2. The end edge 5b is separated from the internal electrode 6 than the end edge 5a. Each of the end edges 5a and 5b may include a face. The end edges 5a and 5b are adjacent to the face 5c and the face 5d. The pair of faces 5c and 5d are opposed to each other. In the present embodiment, the pair of faces 5c and 5d are opposed to each other in the third direction D3. The internal electrode 5 is separated from the end surface 2b and the side surfaces 2c, 2d, 2e, and 2f. For example, when the end edge 5a includes a first end edge of the internal electrode 5, the end edge 5b includes a second end edge of the internal electrode 5.

The end 5e is exposed to the surface of the element body 2. The end 5e is exposed to the end surface 2a. The end 5e is connected to the external electrode 3. In the present embodiment, the end 5e is directly connected to the external electrode 3. The end 5e includes a connection end connected to the external electrode 3. The end 5e includes a distal end face.

The end 5f is positioned in the element body 2. The end 5f is separated from the surface of the element body 2. The end 5f is not exposed to the surface of the element body 2. The end 5f is separated from each of the end surfaces 2a and 2b. In the present embodiment, the end 5f includes a distal end of the internal electrode 5 and an area from the distal end of the internal electrode 5 to a predetermined length. Therefore, the end 5f has the predetermined length in the first direction D1. When viewed from the third direction D3, the end 5f is separated from the external electrode 4 and does not overlap the external electrode 4. For example, when the end 5e includes a first end, the end 5f includes a second end.

The internal electrode 6 includes a pair of end edges 6a and 6b, a pair of faces 6c and 6d, and a pair of ends 6e and 6f. The pair of end edges 6a and 6b are opposed to each other. In the present embodiment, the pair of end edges 6a and 6b are opposed to each other in the second direction D2. The end edge 6a is opposed to the internal electrode 5. The end edge 6a is opposed to the internal electrode 5 in the second direction D2. In the present embodiment, the end edge 6a is opposed to the end edge 5a in the second direction D2. That is, in the present embodiment, the end edges 5a and 6a are opposed to each other in the second direction D2. The end edge 6b is separated from the internal electrode 5 than the end edge 6a. Each of the end edges 6a and 6b may include a face. The end edges 6a and 6b are adjacent to the face 6c and the face 6d. The pair of faces 6c and 6d are opposed to each other. In the present embodiment, the pair of faces 6c and 6d are opposed to each other in the third direction D3. The internal electrode 6 is separated from the end surface 2a and the side surfaces 2c, 2d, 2e, and 2f. For example, when the end edge 6a includes a first end edge of the internal electrode 6, the end edge 6b includes a second end edge of the internal electrode 6.

The end 6e is exposed to the surface of the element body 2. The end 6e is exposed to the end surface 2b. The end 6e is connected to the external electrode 4. In the present embodiment, the end 6e is directly connected to the external electrode 4. The end 6e includes a connection end connected to the external electrode 4. The end 6e includes a distal end face.

The end of is positioned in the element body 2. The end of is separated from the surface of the element body 2. The end of is not exposed to the surface of the element body 2. The end of is separated from each of the end surfaces 2a and 2b. In the present embodiment, the end of includes a distal end of the internal electrode 6 and an area from the distal end of the internal electrode 6 to a predetermined length. Therefore, the end of has the predetermined length in the first direction D1. When viewed from the third direction D3, the end of is separated from the external electrode 3 and does not overlap the external electrode 3. For example, when the end 6e includes a third end, the end of includes a fourth end.

The external electrodes 3 and 4 and the internal electrodes 5 and 6 include an electrically conductive material. The electrically conductive material includes, for example, Ag, Pd, Au, Pt, Cu, Ni, Al, Mo, or W. The electrically conductive material may include, for example, an Ag-Pd alloy, an Ag-Cu alloy, an Ag-Au alloy, or an Ag-Pt alloy. The external electrodes 3 and 4 and the internal electrodes 5 and 6 may include the same electrically conductive material. The external electrodes 3 and 4 and the internal electrodes 5 and 6 may include electrically conductive materials different from each other.

The external electrodes 3 and 4 are formed, for example, through baking an electrically conductive paste applied to an outer surface of the element body 2. The electrically conductive paste for forming the external electrodes 3 and 4 includes the above electrically conductive material. The internal electrodes 5 and 6 are formed through, for example, sintering the electrically conductive paste applied on the insulator green sheet together with the insulator green sheet. The electrically conductive paste is applied onto the insulator green sheet by, for example, printing. The conductive paste for forming the internal electrodes 5 and 6 also includes the above electrically conductive material.

As illustrated in FIGS. 2 to 4, the discharge auxiliary portion 7 is disposed in the element body 2. The discharge auxiliary portion 7 is in contact with the internal electrode 5 and the internal electrode 6. The discharge auxiliary portion 7 is separated from the surface of the element body 2. The discharge auxiliary portion 7 is not exposed from the element body 2. The discharge auxiliary portion 7 includes a pair of end edges 7a and 7b opposed to each other and a pair of end edges 7c and 7d opposed to each other. The pair of end edges 7a and 7b are opposed to each other in the first direction D1, and the pair of end edges 7c and 7d are opposed to each other in the second direction D2. In the present embodiment, the end edge 7a is positioned closer to the end surface 2a, and the end edge 7b is positioned closer to the end surface 2b. The end edge 7c is positioned closer to the side surface 2f, and the end edge 7d is positioned closer to the side surface 2e. The discharge auxiliary portion 7 has a rectangular shape defined by the four end edges 7a, 7b, 7c, and 7d when viewed from the third direction D3. The discharge auxiliary portion 7 may have a rectangular shape with rounded corners or a rectangular shape with chamfered corners. The discharge auxiliary portion 7 is separated from the outer surface of the element body 2.

The discharge auxiliary portion 7 further includes a pair of faces 7e and 7f opposed to each other. The pair of faces 7e and 7f are opposed to each other in the third direction D3. The face 7e is in contact with the internal electrodes 5 and 6. The face 7e is in contact with the face 5d of the internal electrode 5 and the face 6d of the internal electrode 6. The internal electrodes 5 and 6 are disposed on the face 7e. The face 7e includes an area covered with the internal electrodes 5 and 6 and an area exposed from the internal electrodes 5 and 6. The face 7f is in contact with the element body 2. The entire face 7f is covered with the element body 2. The discharge auxiliary portion 7 is in contact with the internal electrodes 5 and 6 and connects the internal electrodes 5 and 6 to each other. The internal electrode 5 and the internal electrode 6 are connected to each other via the discharge auxiliary portion 7. A transient voltage suppressor includes the discharge auxiliary portion 7 and the internal electrodes 5 and 6. The transient voltage suppressor has a transient voltage absorption capability.

The discharge auxiliary portion 7 includes an insulator and metal particles. The insulator includes, for example, a ceramic material. The ceramic material is selected from a group consisting of, for example, Fe₂O₃, NiO, CuO, ZnO, MgO, SiO₂, TiO₂, MnCO₃, SrCO₃, CaCO₃, BaCO₃, Al₂O₃, ZrO₂, and B₂O₃. The discharge auxiliary portion 7 may include only one ceramic material selected from this group, or may include two or more ceramic materials selected from this group. The metal particles include, for example, Ag, Pd, Au, Pt, an Ag-Pd alloy, an Ag-Cu alloy, an Ag-Au alloy, or an Ag-Pt alloy. The discharge auxiliary portion 7 may include semiconductor particles. The semiconductor particles include, for example, RuO₂. The discharge auxiliary portion 7 may include glass.

The discharge auxiliary portion 7 is formed through, for example, sintering a slurry applied on the insulator green sheet together with the insulator green sheet. The slurry includes the above ceramic material and metal particle. The slurry is applied onto the insulator green sheet by, for example, printing.

As illustrated in FIGS. 3 and 4, the element body 2 is formed with a cavity S inside. The cavity S is separated from the outer surface of the element body 2. A face defining the cavity S includes an inner wall of the element body 2, the end edges 5a and 5b and the face 5c of the internal electrode 5, and the end edges 6a and 6b and the face 6c of the internal electrode 6. The face defining the cavity S also includes an area exposed from the internal electrodes 5 and 6 of the discharge auxiliary portion 7. The discharge auxiliary portion 7 includes an area exposed to the cavity S.

The cavity S is formed, for example, by sintering an organic lacquer applied on the insulator green sheet together with the insulator green sheet. The cavity S is formed through burning down of the organic lacquer. The organic lacquer includes an organic solvent and an organic binder. The organic lacquer is applied onto the insulator green sheet by, for example, printing.

As illustrated in FIG. 3, the end 5f of the internal electrode 5 and the end of 6f the internal electrode 6 are positioned between the pair of end edges 7a and 7b of the discharge auxiliary portion 7 in the first direction D1. In the present embodiment, a distal end of the end 5f and a distal end of the end of are positioned between the pair of end edges 7a and 7b in the first direction D1. The end 5f and the end 6f are positioned inside of the discharge auxiliary portion 7 when viewed from the third direction D3. The end 5f and the end 6f may not be positioned between the pair of end edges 7a and 7b in the first direction D1. The end 5f may be positioned between the end edge 7b and the end surface 2b in the first direction D1. The end 6f may be positioned between the end edge 7a and the end surface 2a in the first direction D1. The pair of end edges 7a and 7b may be positioned between the distal end of the end 5f and the distal end 6f the end of in the first direction D1. The end 5f and the end 6f may be positioned outside of the discharge auxiliary portion 7 when viewed from the third direction D3. The distal end of the end 5f may overlap the end edge 7b when viewed from the third direction D3. The distal end of the end of may overlap the end edge 7a when viewed from the third direction D3.

The end edge 5b of the internal electrode 5 and the end edge 6b of the internal electrode 6 are positioned, for example, between the pair of end edges 7c and 7d in the second direction D2. The end edge 5b and the end edge 6b may not be positioned between the pair of end edges 7c and 7d in the second direction D2. The end edge 5b may be positioned between the end edge 7d and the side surface 2e in the second direction D2. The end edge 6b may be positioned between the end edge 7c and the side surface 2f in the second direction D2. The pair of end edges 7c and 7d may be positioned between the end edge 5b and the end edge 6b in the second direction D2. The end edge 7c may be positioned, for example, between the end edge 6a and the end edge 6b in the second direction D2. The end edge 7d may be positioned, for example, between the end edge 5a and the end edge 5b in the second direction D2. The end edge 5b may overlap the end edge 7d when viewed from the third direction D3. The end edge 6b may overlap the end edge 7c when viewed from the third direction D3.

The distal end of the end 5f overlaps, for example, an end S1 which is one end of the cavity S in the first direction D1 when viewed from the third direction D3 and is closer to the end surface 2b. The distal end of the end 6f overlaps, for example, an end S2 which is the other end of the cavity S in the first direction D1 when viewed from the third direction D3 and is closer to the end surface 2a.

The distal end of the end 5f may not overlap the end S1 when viewed from the third direction D3. The distal end of the end 5f may be positioned inside the cavity S or outside the cavity S when viewed from the third direction D3. The distal end of the end 5f may be positioned between the end S1 and the end S2 or may be positioned between the end S1 and the end surface 2b in the second direction D2.

The distal end of the end 6f may not overlap the end S2 when viewed from the third direction D3. The distal end of the end of may be positioned inside the cavity S or outside the cavity S when viewed from the third direction D3. The distal end of the end 6f may be positioned between the end S1 and the end S2 or between the end S2 and the end surface 2a in the second direction D2.

For example, the end edge 5b and the end edge 6b are positioned, in the second direction D2, between an end S3 which is one end of the cavity S in the second direction D2 and is closer to the side surface 2e, and an end S4 which is the other end of the cavity S in the second direction D2 and is closer to the side surface 2f. The end edge 5b and the end edge 6b may not be positioned between the end S3 and the end S4 in the second direction D2. The end edge 5b may be positioned between the end S3 and the side surface 2e in the second direction D2. The end edge 6b may be positioned between the end S4 and the side surface 2f in the second direction D2. The end S3 and the end S4 may be positioned between the end edge 5b and the end edge 6b in the second direction D2. The end edge 5b may overlap the end S3 when viewed from the third direction D3. The end edge 6b may overlap the end S4 when viewed from the third direction D3.

In the present embodiment, the ends S1 and S2 are positioned between the pair of end edges 7a and 7b in the first direction D1. The ends S1 and S2 are positioned inside of the discharge auxiliary portion 7 when viewed from the third direction D3. The ends S1 and S2 may not be positioned between the pair of end edges 7a and 7b in the first direction D1. The end S1 may be positioned between the end edge 7b and the end surface 2b in the first direction D1. The end S2 may be positioned between the end edge 7a and the end surface 2a in the first direction D1. The end S1 and the end S2 may be positioned outside of the discharge auxiliary portion 7 when viewed from the third direction D3. The end S1 may overlap the end edge 7a when viewed from the third direction D3. The end S2 may overlap the end edge 7b when viewed from the third direction D3.

In the present embodiment, the end S3 overlaps the end edge 7d when viewed from the third direction D3, for example. The end S4 overlaps the end edge 7c when viewed from the third direction D3, for example.

The end S3 may not overlap the end edge 7d when viewed from the third direction D3. The end S3 may be positioned inside of the discharge auxiliary portion 7 or outside of the discharge auxiliary portion 7 as viewed from the third direction D3. The end S3 may be positioned between the pair of end edges 7c and 7d or between the end edge 7d and the side surface 2e in the second direction D2.

The end S4 may not overlap the end edge 7c when viewed from the third direction D3. The end S4 may be positioned inside of the discharge auxiliary portion 7 or outside of the discharge auxiliary portion 7 as viewed from the third direction D3. The end S4 may be positioned between the pair of end edges 7c and 7d or between the end edge 7c and the side surface 2f in the second direction D2.

A length d1 of the cavity S in the first direction D1 is equal to or more than a shortest distance d3. A length d2 of the cavity S in the second direction D2 is equal to or more than the shortest distance d3. The shortest distance d3 is a distance between the internal electrode 5 and the internal electrode 6 at a position where the internal electrode 5 and the internal electrode 6 are opposed to each other. The length d1 includes, for example, a distance between the end S1 and the end S2 in the first direction D1. The length d2 includes, for example, a distance between the end S3 and the end S4 in the second direction D2. The shortest distance d3 includes, for example, a shortest distance between the end edge 5a and the end edge 6a at the position where the internal electrode 5 and the internal electrode 6 are opposed to each other.

The length d1 may be, for example, equal to or less than a length of the discharge auxiliary portion 7 in the first direction D1, or may be more than the length of the discharge auxiliary portion 7 in the first direction D1. The length d2 may be, for example, equal to or less than a length of the discharge auxiliary portion 7 in the second direction D2, or may be more than the length of the discharge auxiliary portion 7 in the second direction D2. The length of the discharge auxiliary portion 7 in the first direction D1 includes, for example, a distance between the end edge 7a and the end edge 7b in the first direction D1. The length of the discharge auxiliary portion 7 in the second direction D2 includes, for example, a distance between the end edge 7c and the end edge 7d in the second direction D2.

As described above, in the present embodiment, the end 5f has the predetermined length in the first direction D1. As illustrated in FIG. 5, in the present embodiment, opposite ends of the end 5f in the first direction D1 are defined by points P1, P2, and P3. The point P1 is, for example, one end of the end 5f in the first direction D1, and is the distal end of the end 5f. The point P2 and the point P3 are positioned, for example, at the other end of the end 5f in the first direction D1, and are positioned closer to the end 5e than the point P1. In the present embodiment, positions of the point P2 and the point P3 in the first direction D1 are the same, and the point P2 is positioned closer to the internal electrode 6 than the point P3.

The end 5f of the internal electrode 5 includes a pair of corner portions 51 and 52 adjacent to each other in the second direction D2.

In the present embodiment, the corner portion 51 is formed by the face 5c and the end edge 5a at the end 5f. The corner portion 51 includes an edge 51a opposed to the internal electrode 6. The edge 51a is included, for example, in the end edge 5a. That is, the end edge 5a includes, for example, the edge 51a. In the present embodiment, a part of the end edge 5a positioned between the point P1 and the point P2 includes the edge 51a.

The corner portion 52 is formed by the face 5c and the end edge 5b at the end 5f. The corner portion 52 includes an edge 52a. The edge 52a is included, for example, in the end edge 5b. That is, the end edge 5b includes, for example, the edge 52a. In the present embodiment, a part of the end edge 5b positioned between the point P1 and the point P3 includes the edge 52a.

The edge 51a has a curved shape in a plan view of the internal electrode 5. That is, in the internal electrode 5, a corner of the corner portion 51 is rounded at the end 5f. The plan view of the internal electrode 5 includes, for example, viewing the face 5c of the internal electrode 5 from the third direction D3. In the present embodiment, the edge 51a has the curved shape between the points P1 and P2 in the plan view of the internal electrode 5. For example, the edge 51a has the curved shape such that a distance between the edge 51a and the internal electrode 6 in the second direction D2 increases as it gets closer to the point P1. That is, at the end 5f, the distance between internal electrodes 5 and 6 in the second direction D2 increases as it gets closer to the distal end of the end 5f.

In the present embodiment, a radius of curvature R1 of the edge 51a is, for example, constant between the point P1 and the point P2. In the present embodiment, the radius of curvature R1 is the same as a width of the internal electrode 5. That is, in the present embodiment, the edge 51a has the radius of curvature R1 having the same length as the width of the internal electrode 5. The width of the internal electrode 5 includes, for example, a length of the internal electrode 5 in the second direction D2. The length of the internal electrode 5 in the second direction D2 includes, for example, a distance between the end edge 5a and the end edge 5b in the second direction D2 at a position closer to the end 5e than the points P2 and P3. The radius of curvature R1 may not be constant between the point P1 and the point P2, for example.

In the present embodiment, the edge 52a does not have the curved shape in the plan view of the internal electrode 5. For example, the edge 52a extends along the first direction D1 in the plan view of the internal electrode 5. That is, in the internal electrode 5, a corner of the corner portion 52 is not rounded at the end 5f.

For example, when the corner portion 51 includes a first corner portion of the internal electrode 5, the corner portion 52 includes a second corner portion of the internal electrode 5.

As described above, in the present embodiment, the end 6f has the predetermined length in the first direction D1. In the present embodiment, opposite ends of the end 6f in the first direction D1 are defined by points P4, P5, and P6. The point P4 is, for example, one end of the end of in the first direction D1, and is the distal end of the end 6f. The point P5 and the point P6 are positioned, for example, at the other end of the end of in the first direction D1, and are positioned closer to the end 6e than the point P4. In the present embodiment, the positions of the point P5 and the point P6 in the first direction D1 are the same, and the point P5 is positioned closer to the internal electrode 5 than the point P6.

The end 6f of the internal electrode 6 includes a pair of corner portions 61 and 62 adjacent to each other in the second direction D2.

In the present embodiment, the corner portion 61 is formed by the face 6c and the end edge 6a at the end 6f. The corner portion 61 includes an edge 61a opposed to the internal electrode 5. The edge 61a is included, for example, in the end edge 6a. That is, the end edge 6a includes, for example, the edge 61a. In the present embodiment, a part of the end edge 6a positioned between the point P4 and the point P5 includes the edge 61a.

The corner portion 62 is formed by the face 6c and the end edge 6b at the end 6f. The corner portion 62 includes an edge 62a. The edge 62a is included, for example, in the end edge 6b. That is, the end edge 6b includes, for example, the edge 62a. In the present embodiment, a part of the end edge 6b positioned between the point P4 and the point P6 includes the edge 62a.

The edge 61a has the curved shape in a plan view of the internal electrode 6. That is, in the internal electrode 6, a corner of the corner portion 61 is rounded at the end 6f. The plan view of the internal electrode 6 includes, for example, viewing the face 6c of the internal electrode 6 from the third direction D3. In the present embodiment, the edge 61a has the curved shape between the points P4 and P5 in the plan view of the internal electrode 6. For example, the edge 61a has the curved shape such that a distance between the edge 61a and the internal electrode 5 in the second direction D2 increases as it gets closer to the point P4. That is, at the end 6f, the distance between the internal electrode 5 and the internal electrode 6 in the second direction D2 increases, as it gets closer to the distal end of the end 6f.

In the present embodiment, a radius of curvature R2 of the edge 61a is, for example, constant between the point P4 and the point P5. In the present embodiment, the radius of curvature R2 is the same as a width of the internal electrode 6. That is, in the present embodiment, the edge 61a has the radius of curvature R2 having the same length as the width of the internal electrode 6. The width of the internal electrode 6 includes, for example, a length of the internal electrode 6 in the second direction D2. The length of the internal electrode 6 in the second direction D2 includes, for example, a distance between the end edge 6a and the end edge 6b in the second direction D2 at a position closer to the end 6e than the points P5 and P6. In the present embodiment, the radius of curvature R1 and the radius of curvature R2 are the same. The radius of curvature R1 and the radius of curvature R2 may be different from each other. The radius of curvature R2 may not be constant between the point P4 and the point P5, for example.

In the present embodiment, the edge 62a does not have the curved shape in the plan view of the internal electrode 6. For example, the edge 62a extends along the first direction D1 in plan view of the internal electrode 6. That is, in the internal electrode 6, a corner of the corner portion 62 is not rounded at the end 6f.

For example, when the corner portion 61 includes a third corner portion of the internal electrode 6, the corner portion 62 includes a fourth corner portion of the internal electrode 6.

As described above, in the transient voltage protection device 1, the edge 51a included in the corner portion 51 has the curved shape in the plan view of the internal electrode 5. Therefore, an electric field tends not concentrate a region of the end 5f, and discharge tends not to concentrate locally.

Similarly, in the transient voltage protection device 1, the edge 61a included in the corner portion 61 has the curved shape in the plan view of the internal electrode 6. Therefore, the electric field tends not concentrate a region of the end 6f, and discharge tend not to concentrate locally.

As a result of the above, the transient voltage protection device 1 can control deterioration of the transient voltage protection characteristic.

As described above, the internal electrodes 5 and 6 are formed through, for example, sintering the electrically conductive paste that has been applied on the insulator green sheet together with the insulator green sheet. On the insulator green sheet to which the above electrically conductive paste is applied, a slurry to be the discharge auxiliary portion 7 is applied. That is, when the internal electrodes 5 and 6 are formed, the electrically conductive paste to be the internal electrodes 5 and 6 is applied onto the insulator green sheet over the slurry to be the discharge auxiliary portion 7. At this time, in a case where the above electrically conductive paste is applied onto the insulator green sheet so that the end 5f and the end of are positioned outside of the pair of end edges 7a and 7b in the first direction D1, at positions to become the end edges 7a and 7b, the electrically conductive paste may spread outward from the place where it is applied.

When the insulator green sheet is fired in a state where the conductive paste spreads outward from the place where it is applied, the internal electrode 5 and the internal electrode 6 are electrically connected to each other on outside of the discharge auxiliary portion 7, and a short circuit may occur. By contrast, when the above electrically conductive paste is applied onto the insulator green sheet so that the end 5f and the end of are positioned between the pair of end edges 7a and 7b in the first direction D1, even if the conductive paste may spread outward from the place where it is applied, the internal electrode 5 and the internal electrode 6 tend not to be electrically connected. That is, in the transient voltage protection device 1 in which the end 5f and the end of are positioned between the pair of end edges 7a and 7b in the first direction D1, the occurrence of a short circuit between the internal electrode 5 and the internal electrode 6 is suppressed. That is, the transient voltage protection device 1 in which the end 5f and the end of are positioned between the pair of end edges 7a and 7b in the first direction D1, controls the short circuit between the internal electrode 5 and the internal electrode 6.

In the transient voltage protection device 1, the length of the discharge auxiliary portion 7 in the second direction D2 may decrease due to repeated discharge generated between the internal electrode 5 and the internal electrode 6. The decrease of the length of the discharge auxiliary portion 7 in the second direction D2 may cause the pair of end edges 7c and 7d to be positioned between the end edge 5a and the end edge 6a in the second direction D2, and may prevent the discharge auxiliary portion 7 from being contact with the internal electrode 5 and the internal electrode 6. In a configuration in which the discharge auxiliary portion 7 is not in contact with the internal electrode 5 and the internal electrode 6, a discharge starting voltage increases, and the transient voltage protection characteristic may be deteriorated. By contrast, in the transient voltage protection device 1 in which each of the end edges 5b and 6b is positioned between the pair of end edges 7c and 7d in the second direction D2, even when the length of the discharge auxiliary portion 7 in the second direction D2 decrease, the discharge auxiliary portion 7 tends to be contact with the internal electrode 5 and the internal electrode 6. As a result, the transient voltage protection device 1 can further control the deterioration of the transient voltage protection characteristic.

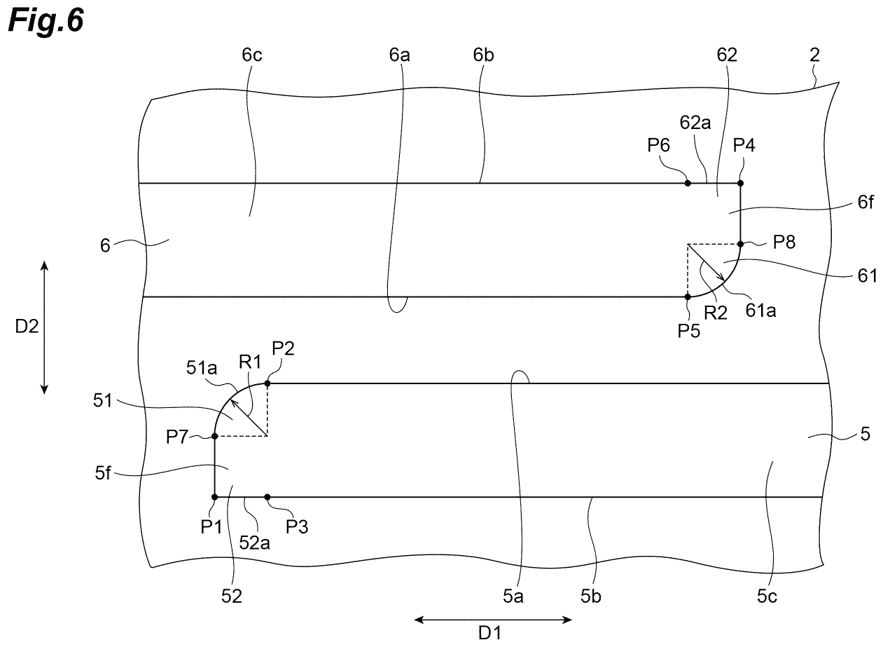

Next, a modification of the transient voltage protection device 1 according to the present embodiment will be described with reference to FIG. 6. FIG. 6 is a plan view illustrating a configuration of another internal electrode. In the present modification, configurations of the internal electrode 5 and the internal electrode 6 are different from those of the above-described embodiment. In the following, differences between the above-described embodiment and the present modification will be mainly described.

As illustrated in FIG. 6, in the present modification, the edge 51a has the curved shape between the point P2 and a point P7 in the plan view of the internal electrode 5. The point P7 is positioned at the same as the point P1 in the first direction D1, and is positioned between the point P2 and the point P3 in the second direction D2. In the present modification, for example, the edge 51a has the curved shape such that the distance between the edge 51a and the internal electrode 6 in the second direction D2 increases as it gets closer to the point P7. As described above, since a position of the point P7 in the first direction D1 is the same as the position of the point P1 in the first direction D1, also in the present modification, at the end 5f, the distance between the internal electrode 5 and the internal electrode 6 in the second direction D2 increases as it gets closer to the distal end of the end 5f.

In the present modification, the radius of curvature R1 is constant between the point P2 and the point P7, for example. In the present modification, the radius of curvature R1 is smaller than the width of the internal electrode 5. The edge 51a has the radius of curvature R1 of a length smaller than the width of the internal electrode 5. The radius of curvature R1 may be, for example, a length of ¼ or more and ½ or less of the width of the internal electrode 5. In the present modification, the radius of curvature R1 is ½ of the width of the internal electrode 5. The radius of curvature R1 may not be constant between the point P2 and the point P7.

In the present embodiment, the edge 61a has the curved shape between the point P5 and a point P8 in the plan view of the internal electrode 6. The point P8 is positioned at the same as the point P4 in the first direction D1, and is positioned between the point P5 and the point P6 in the second direction D2. In the present modification, for example, the edge 61a has the curved shape such that the distance between the edge 61a and the internal electrode 5 in the second direction D2 increases as it gets closer to the point P8. As described above, since a position of the point P8 in the first direction D1 is the same as the position of the point P4 in the first direction D1, also in the present modification, at the end 6f, the distance between the internal electrode 5 and the internal electrode 6 in the second direction D2 increases as it gets closer to the distal end of the end 6f.

In the present modification, the radius of curvature R2 is constant between the point P5 and the point P8, for example. In the present modification, the radius of curvature R2 is smaller than the width of the internal electrode 6. The edge 61a has the radius of curvature R2 of a length smaller than the width of the internal electrode 6. The radius of curvature R2 may be, for example, a length of ¼ or more and ½ or less of the width of the internal electrode 6. In the present modification, the radius of curvature R2 is ½ of the width of the internal electrode 6. The radius of curvature R2 may not be constant between the point P5 and the point P8.

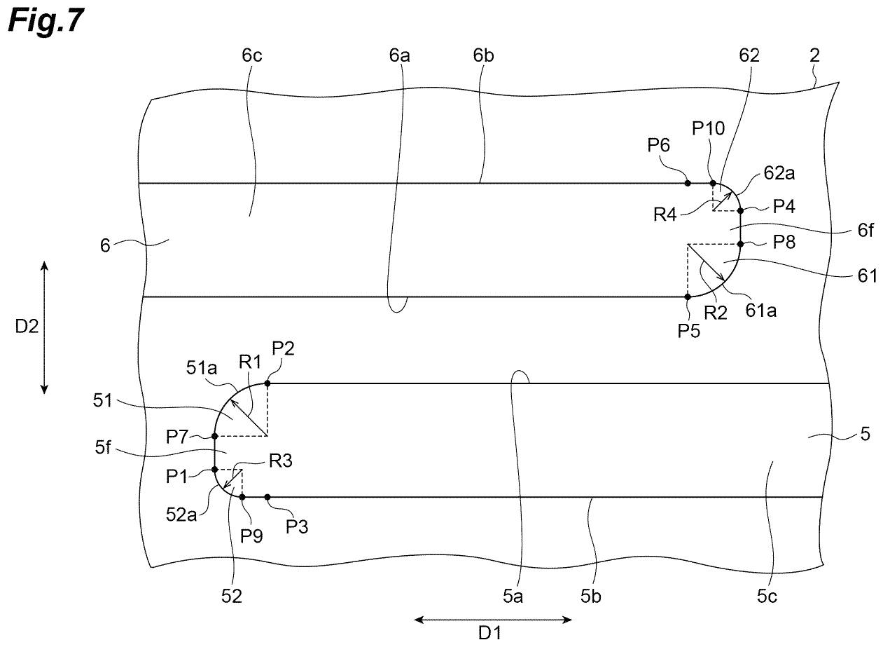

Next, a further modification of the transient voltage protection device 1 according to the present embodiment will be described with reference to FIG. 7. FIG. 7 is a plan view illustrating a configuration of a further internal electrode. In the present modification, configurations of the internal electrode 5 and the internal electrode 6 are different from those of the above-described modification. In the following, differences between the above-described modification and the present modification will be mainly described.

As illustrated in FIG. 7, in the present modification, the edge 52a has the curved shape in the plan view of the internal electrode 5. That is, in the present modification, the corner portion 52 includes the edge 52a having the curved shape in the plan view of the internal electrode 5. For example, the edge 52a has the curved shape between a point P9 and the point P1 in the plan view of the internal electrode 5. The point P9 is positioned between the point P1 and the point P3 in the first direction D1, and is positioned at the same as the point P3 in the second direction D2. In the present modification, the edge 52a has the curved shape such that a distance between the edge 52a and the side surface 2e in the second direction D2 increases as it gets closer to the point P1. The edge 52a extends along the first direction D1 between the point P3 and the point P9 in the plan view of the internal electrode 5. That is, in the present modification, the edge 52a includes a part having the curved shape and a part extending along the first direction D1 in the plan view of the internal electrode 5.

In the present modification, a radius of curvature R3 of the edge 52a is constant between the point P1 and the point P9, for example. As illustrated in FIG. 7, in the present modification, the radius of curvature R3 is smaller than the radius of curvature R1. That is, the edge 51a has the radius of curvature R1 larger than the radius of curvature R3 of the edge 52a. The radius of curvature R3 may be, for example, ⅙ or more and ½ or less of the radius of curvature R1. The radius of curvature R3 may be the same as the radius of curvature R1.

In the present modification, the edge 62a has the curved shape in the plan view of the internal electrode 6. That is, in the present modification, the corner portion 62 includes the edge 62a having the curved shape in the plan view of the internal electrode 6. The edge 62a has the curved shape, for example, between the point P4 and a point P10 in the plan view of the internal electrode 6. The point P10 is positioned between the point P4 and the point P6 in the first direction D1, and is positioned at the same as the point P6 in the second direction D2. In the present modification, the edge 62a has the curved shape such that a distance between the edge 62a and the side surface 2f in the second direction D2 increases as it gets closer to the point P4. The edge 62a extends along the first direction D1 between the point P6 and the point P10 in the plan view of the internal electrode 6. That is, in the present modification, the edge 62a includes a part having the curved shape and a part extending along the first direction D1 in the plan view of the internal electrode 6.

In the present modification, a radius of curvature R4 of the edge 62a is constant between the point P4 and the point P10, for example. In the present modification, the radius of curvature R4 is smaller than the radius of curvature R2. That is, the edge 61a has the radius of curvature R2 larger than the radius of curvature R4 of the edge 62a. The radius of curvature R4 may be, for example, ⅙ or more and ½ or less of the radius of curvature R2. In the present modification, the radius of curvature R4 is ½ of the radius of curvature R2. The radius of curvature R4 may be the same as the radius of curvature R2.

Although the embodiment and the modifications of the present disclosure have been described in the foregoing, the present disclosure is not necessarily limited to the above-described embodiment and modifications, and various changes can be made without departing from the gist thereof.

In the embodiment and the modifications described above, the edge 51a of the corner portion 51 has the curved shape in the plan view of the internal electrode 5, and the edge 61a of the corner portion 61 has the curved shape in the plan view of the internal electrode 6. However, in both the internal electrode 5 and the internal electrode 6, the edge 51a and the edge 61a may not have the curved shape as described above. For example, in the transient voltage protection device 1, the edge 51a may have the curved shape in the plan view of the internal electrode 5, and the edge 61a may not have the curved shape in the plan view of the internal electrode 6. Alternatively, in the transient voltage protection device 1, the edge 61a may have the curved shape in the plan view of the internal electrode 6, and the edge 51a may not have the curved shape in the plan view of the internal electrode 5. That is, one of the internal electrode 5 and the internal electrode 6 may have a rectangular shape in the plan view of the internal electrode.

What is claimed is:

1. A transient voltage protection device, comprising:
an element body including a surface;
a first external electrode disposed on the surface of the element body;
a second external electrode disposed on the surface of the element body and separated from the first external electrode;
a first internal electrode disposed in the element body and connected to the first external electrode; and
a second internal electrode opposed to the first internal electrode in the element body and connected to the second external electrode, wherein
the first internal electrode includes:
a first end exposed to the surface of the element body and connected to the first external electrode; and
a second end positioned in the element body and separated from the surface of the element body,
the second end includes a first corner portion and a second corner portion that are adjacent to each other in a direction in which the first internal electrode and the second internal electrode are opposed to each other, the first corner portion including an edge opposed to the second internal electrode, the second corner portion separated from the second internal electrode than the first corner portion, and
the edge included in the first corner portion has a curved shape in a plan view of the first internal electrode.

2. The transient voltage protection device according to claim 1, wherein
the second corner portion includes an edge having a curved shape in the plan view of the first internal electrode, and
the edge included in the first corner portion has a radius of curvature larger than a radius of curvature of the edge included in the second corner portion.

3. The transient voltage protection device according to claim 1, wherein
the first internal electrode and the second internal electrode are positioned in the same layer.

4. The transient voltage protection device according to claim 1, wherein
the edge included in the first corner portion has a radius of curvature of the same length as a width of the first internal electrode.

5. The transient voltage protection device according to claim 1, further comprising:
a discharge auxiliary portion disposed in the element body and in contact with the first internal electrode and the second internal electrode, wherein
the second internal electrode includes:
a third end exposed to the surface of the element body and connected to the second external electrode; and
a fourth end positioned in the element body and separated from the surface of the element body,
the discharge auxiliary portion includes a pair of end edges opposed to each other in a direction in which the first external electrode and the second external electrode are separated from each other, and
the second end and the fourth end are positioned between the pair of end edges in the direction in which the first external electrode and the second external electrode are separated from each other.

6. The transient voltage protection device according to claim 5, wherein
each of the first internal electrode and the second internal electrode includes a first end edge and a second end edge opposed to each other in the direction in which the first internal electrode and the second internal electrode are opposed to each other,
each of the first end edges is opposed to the other in the direction in which the first internal electrode and the second internal electrode are opposed to each other, and
each of the second end edges is separated from a corresponding internal electrode of the first internal electrode and the second internal electrode than the first end edge,
the discharge auxiliary portion includes another pair of end edges opposed to each other in the direction in which the first internal electrode and the second internal electrode are opposed to each other, and
each of the second end edges is positioned between the other pair of end edges in the direction in which the first internal electrode and the second internal electrode are opposed to each other.

7. The transient voltage protection device according to claim 1, wherein
the element body is formed with a cavity inside,
the first internal electrode and the second internal electrode are opposed to each other in the cavity,
a length of the cavity in the direction in which the first internal electrode and the second internal electrode are opposed to each other is equal to or more than a shortest distance between the first internal electrode and the second internal electrode at a position where the first internal electrode and the second internal electrode are opposed to each other, and
a length of the cavity in a direction in which the first external electrode and the second external electrode are separated from each other are equal to or more than the shortest distance at the position where the first internal electrode and the second internal electrode are opposed to each other.

8. The transient voltage protection device according to claim 1, wherein
the second internal electrode includes:
a third end exposed to the surface of the element body and connected to the second external electrode; and
a fourth end positioned in the element body and separated from the surface of the element body,
the fourth end includes a third corner portion and a fourth corner portion that are adjacent to each other in the direction in which the first internal electrode and the second internal electrode are opposed to each other, the third corner portion including an edge opposed to the first internal electrode, the fourth corner portion separated from the first internal electrode than the third corner portion, and
the edge included in the third corner portion has a curved shape in a plan view of the second internal electrode.

9. The transient voltage protection device according to claim 8, wherein
the fourth corner portion includes an edge having a curved shape in the plan view of the second internal electrode, and
the edge included in the third corner portion has a radius of curvature larger than a radius of curvature of the edge included in the fourth corner portion.
